(19) United States
(12) Patent Application Publication
(10) Pub. No.: US 2007/0020812 A1
(43) Pub. Date: Jan. 25, 2007

(54) Circuit board structure integrated with semiconductor chip and method of fabricating the same

(75) Inventors: Shih-Ping Hsu, Hsin-chu (TW); Chu-Chin Hu, Hsin-chu (TW)

Correspondence Address: CLARK & BRODY, 1090 VERMONT AVENUE, NW, SUITE 250, WASHINGTON, DC, 20005, US

(73) Assignee: Phoenix Precision Technology Corp.

(21) Appl. No.: 11/184,979

(22) Filed: Jul. 20, 2005

(51) Int. Cl. H01L 21/00

(52) U.S. Cl. 438/119

(57) ABSTRACT

A circuit board structure integrated with semiconductor chip and a method of fabricating the same are proposed. A supporting plate formed with at least one cavity is provided and a semiconductor chip having a plurality of conductive contacts is embedded in the cavity. An anisotropic conductive film (ACF) layer and a circuit board formed with a plurality of conductive contacts on a surface thereof are provided. The circuit board is pressed to the supporting plate by the ACF layer, wherein the conductive contacts of the circuit board are electrically connected to the conductive contacts of the chip via the ACF layer, so as to form the circuit board structure integrated with semiconductor chip.

### FIELD OF THE INVENTION

The present invention relates to circuit board structures integrated with semiconductor chips and methods of fabricating the same, and more particularly, to a circuit board structure capable of integrating a semiconductor chip therein, and a method of fabricating the circuit board structure.

### BACKGROUND OF THE INVENTION

Along with the development of semiconductor packaging technology, various types of packages for semiconductor devices have been developed. One of the advanced semiconductor packaging technologies is BGA (ball grid array) technology, which is characterized by employing a substrate for mounting a semiconductor chip on a front surface thereof and utilizing a self-alignment technique to mount a plurality of solder balls arranged in a grid array on a back surface of the substrate, such that more I/O (input/output) connections can be accommodated in the same unit area of a chip carrier (e.g. the substrate) to satisfy the high-integration requirement of the semiconductor chip, and the entire package unit can be bonded and electrically connected to an external printed circuit board by the solder balls.

Flip-chip semiconductor packaging technology, introduced in the early 1960s by the IBM company, is characterized by the use of solder bumps for electrically connecting a semiconductor chip to a substrate instead of using general gold wires as with wire-bonding technology. Flip-chip technology yields significant advantages, for example increasing packaging density to reduce the size of the package unit, and improving electrical performance as not requiring relatively lengthy metallic wires such that the high-density and high-speed requirements of a semiconductor device can be satisfied.

In current flip-chip technology, a plurality of electrode pads are formed on a surface of a semiconductor IC (integrated circuit) chip, and corresponding contact pads are formed on a circuit board for carrying the chip, such that solder bumps or other conductive adhesive materials can be adequately disposed between the chip and the circuit board, and the chip is mounted on the circuit board in a face-down manner with an active surface of the chip facing the circuit board, wherein the solder bumps or conductive adhesive materials provide electrical input/output (I/O) connection and mechanical connection between the chip and the circuit board.

FIGS. 1A and 1B show a conventional flip-chip semiconductor device. As shown in FIGS. 1A and 1B, a plurality of metallic bumps 11 are formed on electrode pads 12 of a chip 13, and a plurality of pre-solder bumps 14 made of a solder material are formed on contact pads 15 of a circuit board 16. Under a reflow temperature sufficient to make the pre-solder bumps 14 melt, the pre-solder bumps 14 are reflowed to the corresponding metallic bumps 11 to form solder joints 17. A gap between the chip 13 and the circuit board 16 can be filled with an underfill material 18 to reduce any mismatch in thermal expansion between the chip 13 and the circuit board 16 and decrease stresses on the solder joints 17.

At present in the industry, the primary technology for depositing the solder material to form pre-solder bumps on the contact pads of the circuit board is stencil printing technology. In practice, due to the large growth of portable electronic products in the fields of communications, network and computer, packages such as BGA with reduced IC area and characteristics of high density and multiple pins, CSP (chip size package) and MCM (multi chip module) have become the mainstream of the package market and usually cooperate with high-performance chips such as microprocessors, chipsets and graphic chips to achieve high-speed operations. However, such structures must have circuits with reduced width and pads with reduced size. When a pitch between pads is continuously decreased, due to an insulating protective layer formed between the pads and partly covering the pads, portions of the pads exposed from the insulating protective layer become smaller in size. This not only causes an alignment problem in subsequently forming pre-solder bumps but also requires reduction in opening size of a stencil for the stencil printing technology, making the solder material difficult to be deposited on the contact pads due to the occupied space and height of the insulating protective layer, such that the yield of stencil printing technology becomes extremely low, and costs of the stencil are increased in response to the reduction in pad size and pad pitch, leading to undesirable raise of the fabrication costs. Further as the pitch between the pads is reduced, a contact area between the insulating protective layer and the circuit board becomes smaller, making the insulating protective layer less adhesive to the circuit board.

During fabrication processes of flip-chip semiconductor devices, after completing the fabrication of an IC wafer, electrode pads of chips of the wafer are necessarily formed with a UBM (under bump metallurgy) structure for mounting metallic bumps thereon, and a singulation process is performed to cut the wafer into the chips, such that the chips can be subsequently mounted on and electrically connected to circuit boards in a flip-chip manner. The fabrication processes of the UMB structure and metallic bumps comprise the following steps. Firstly, a passivation layer is formed on a surface of the wafer and exposes the electrode pads. Then, the UMB structure comprising a plurality of metallic layers is formed on the electrode pads by sputtering and electroplating techniques. A solder mask layer is applied on the passivation layer and has a plurality of openings for exposing the UBM structure. Subsequently, a solder-material printing process is performed using the stencil printing technology to deposit a solder material such as a Sn/Pb alloy on the UBM structure via the openings of the solder mask layer. A reflow-soldering process is performed to bond the solder material to the UBM structure. Then, the solder mask layer is removed, and the reflow-soldering process is repeated to sphere the solder material to form metallic bumps on the wafer, such that the metallic bumps provide electrical connection between the chips and the circuit boards.

For the flip-chip semiconductor device, it needs to form corresponding electrical connection units (such as metallic bumps and pre-solder bumps) on the chip and the circuit board respectively. This increases steps and costs of the fabrication processes and may also cause the reliability risks during the fabrication processes.

Whether employing the flip-chip packaging technology or wire-bonding packaging technology, fabrication of the circuit board and packaging of the chip both require various fabrication machines and steps, and have complicated fabrication processes and high fabrication costs. During a molding process, the circuit board mounted with the chip is placed into an encapsulation mold, and an epoxy resin material is injected into the mold to form an encapsulant for encapsulating the chip. However in practice, the mold is limited by the design of the semiconductor package such that the size of a molding cavity and a clamping position of the mold may not be perfectly arranged thereby causing a problem of failing to closely clamp the circuit board by the mold. As such, when injecting the epoxy resin material, it is easy for the encapsulant to flash to the surface of the circuit board, which not only reduces the surface smoothness and appearance of the semiconductor package, but also possibly contaminates pad positions on the circuit board where solder balls are to be mounted. Thereby, the electrical connection quality, fabrication quality and product reliability of the semiconductor package are adversely affected.

In general fabrication processes of semiconductor devices, a chip carrier manufacturer (such as a circuit board manufacturer) firstly produces chip carriers suitable for the semiconductor devices and then provides the chip carriers to a semiconductor package manufacturer where the chip carriers are subjected to such as die-bonding, molding and ball-mounting processes and so on, so as to form the semiconductor devices with electronic functions required by clients. The fabrication processes involve various manufacturers (including the chip carrier manufacturer and the semiconductor package manufacturer), which thus require complicated procedures and cause difficulty in interface integration. In case the clients wish to modify the functional design of the semiconductor devices, the associated modification and integration are more complicated, thereby not providing satisfactory flexibility for modification and economic effects.

### SUMMARY OF THE INVENTION

In light of the above drawbacks in the conventional technology, an objective of the present invention is to provide a circuit board structure integrated with semiconductor chip and a method of fabricating the same, which can integrate fabrication of a chip carrier and processes of semiconductor packaging technology to provide greater flexibility in response to clients' requirements and simplify process and interface integration for semiconductor manufacturers.

Another objective of the present invention is to provide a circuit board structure integrated with semiconductor chip and a method of fabricating the same, to avoid various problems caused by forming electrical connection between a semiconductor chip and a circuit board in the conventional technology.

Still another objective of the present invention is to provide a circuit board structure integrated with semiconductor chip and a method of fabricating the same, to simplify an integration form of a circuit board and a semiconductor chip so as to reduce steps and costs of fabrication processes.

A further objective of the present invention is to provide a circuit board structure integrated with semiconductor chip and a method of fabricating the same, to prevent a flash problem caused during a molding process in the conventional technology, so as to effectively improve production quality and product reliability of a semiconductor device.

In accordance with the above and other objectives, the present invention proposes a method of fabricating a circuit board structure integrated with semiconductor chip, comprising the steps of: providing a supporting plate, which can be a general carrier board or circuit board, wherein the supporting plate is formed with at least one through cavity, such that at lease one semiconductor chip having a plurality of conductive contacts is received in the cavity; and providing an anisotropic conductive film (ACF) layer and a circuit board having a plurality of conductive contacts on a surface thereof, such that the circuit board is pressed and mounted to the supporting plate by the ACF layer pressed therebetween, and the conductive contacts of the circuit board are electrically connected to the conductive contacts of the chip via the ACF layer, so as to form the circuit board structure integrated with semiconductor chip. The conductive contacts of the chip comprise electrode pads and conductive bumps formed on the electrode pads. Further, the chip can also be directly electrically connected to the circuit board by the ACF layer having a plurality of conductive particles therein. As a result, steps and costs of fabrication processes are reduced as compared to conventional electrical connecting technology of forming a plurality of openings in a dielectric layer, performing electroplating to electrically connect circuit layers and so on.

By the foregoing fabrication method, the present invention also proposes a circuit board structure integrated with semiconductor chip, comprising a supporting plate, which can be a general carrier board or circuit board, wherein the supporting plate is formed with at least one through cavity; at least one semiconductor chip having a plurality of conductive contacts and received in the cavity of the supporting plate; and at least one circuit board having a plurality of conductive contacts on a surface thereof and mounted to the supporting plate by an anisotropic conductive film (ACF) layer, such that the conductive contacts of the circuit board are electrically connected to the conductive contacts of the semiconductor chip via the ACF layer. The circuit board can be a build-up or laminated and single-layer or multi-layer circuit board formed with a plurality of conductive traces, such that the circuit board can be directly mounted to the supporting plate embedded with the semiconductor chip. This prevents drawbacks such as complicated fabrication processes, increased costs, unsatisfactory reliability and so on caused by mounting and electrically connecting a chip to a circuit board in conventional wire-bonding or flip-chip semiconductor packaging technology.

Therefore, by the circuit board structure integrated with semiconductor chip and the method of fabricating the same in the present invention, at least one semiconductor chip formed with conductive contacts on a surface thereof is provided in advance and is received in a supporting plate formed with a cavity, such that an overall thickness of a semiconductor device can be reduced to satisfy the light-weight and small-size requirements. Further, by means of an anisotropic conductive film (ACF) layer, a circuit board formed with conductive traces is pressed to the supporting plate embedded with the semiconductor chip, allowing conductive contacts of the circuit board to be electrically connected to the conductive contacts of the chip via the ACF layer so as to form the circuit board structure integrated with semiconductor chip. This can combine fabrication of a chip carrier and processes of semiconductor packaging technology to provide greater flexibility in response to clients' requirements and simplify process and interface integration for semiconductor manufacturers, as well as avoid problems associated with electrical connection and molding during conventional semiconductor packaging processes.

### BRIEF DESCRIPTION OF THE DRAWINGS

The present invention can be more fully understood by reading the following detailed description of the preferred embodiments, with reference made to the accompanying drawings, wherein:

FIGS. 1A and 1B (PRIOR ART) are cross-sectional views of a conventional flip-chip semiconductor device; and

FIGS. 2A to 2E are cross-sectional schematic diagrams showing steps of a method of fabricating a circuit board structure integrated with semiconductor chip according to the present invention.

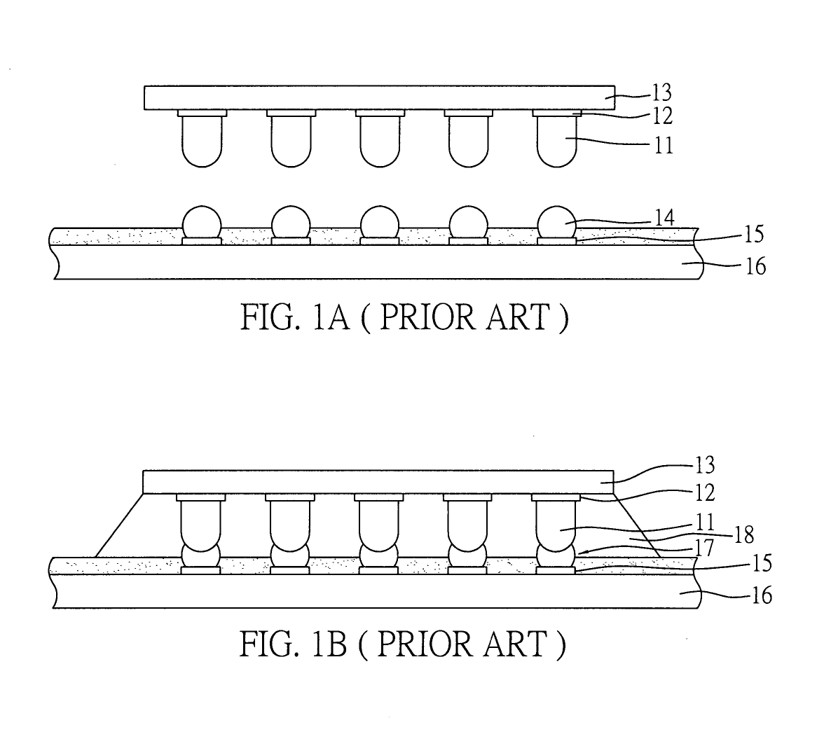

### DETAILED DESCRIPTION OF THE PREFERRED EMBODIMENTS

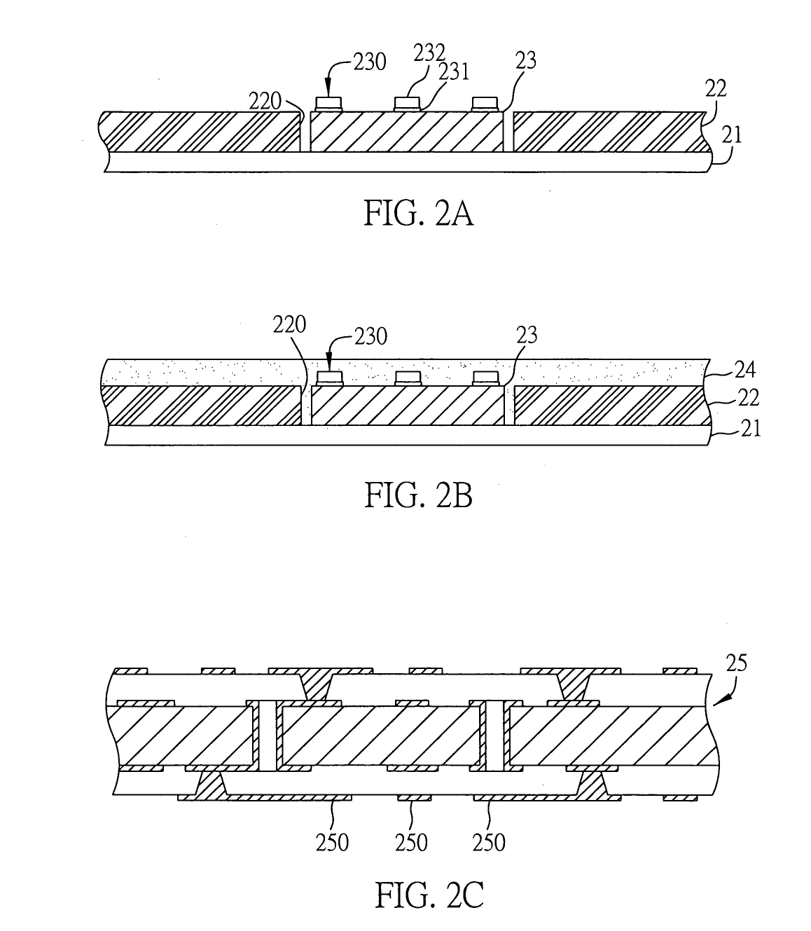

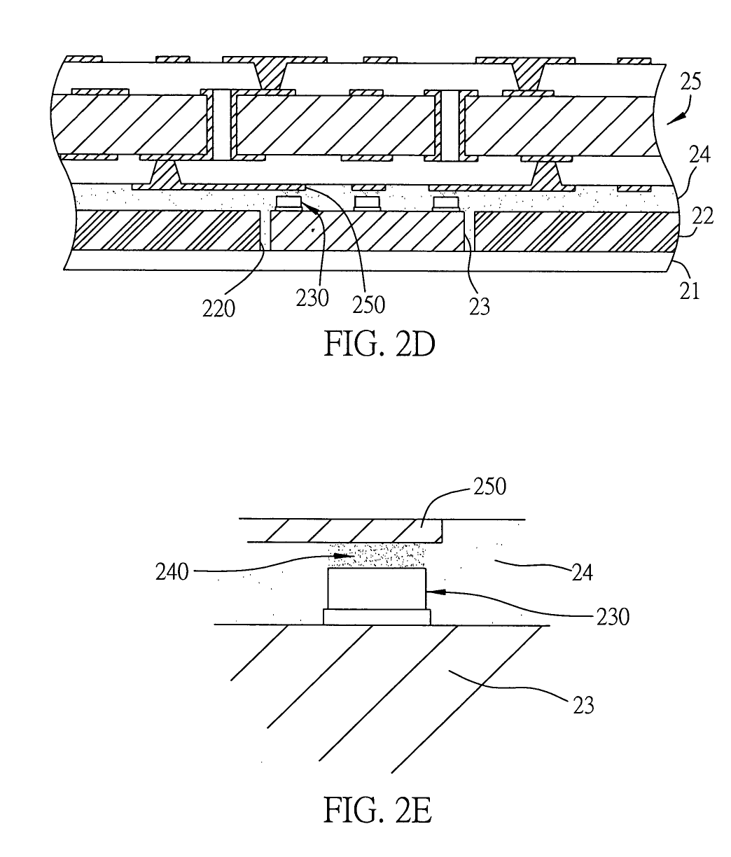

FIGS. 2A to 2E are cross-sectional schematic diagrams showing steps of a method of fabricating a circuit board structure integrated with semiconductor chip according to the present invention.

Referring to FIG. 2A, firstly, a supporting plate 22 is provided, which can be a carrier board such as a metallic plate, insulating plate, etc. or even a circuit board, and the supporting plate 22 is formed with at least one through cavity 220. A carrier 21 can be formed on a side of the supporting plate 22 to seal a side of the cavity 220. The carrier 21 may be an adhesive layer, such that at least one semiconductor chip 23 may be mounted via a surface thereof on the carrier 21 and received in the cavity 220 of the supporting plate 22, wherein conductive contacts 230 on an active surface of the semiconductor chip 23 are exposed from the cavity 220 of the supporting plate 22. The conductive contacts 230 of the semiconductor chip 23 comprise electrode pads 231 formed on the semiconductor chip 23 and conductive bumps 232 formed by electroplating on the electrode pads 231.

Referring to FIGS. 2B and 2C, an anisotropic conductive film (ACF) layer 24 and a circuit board 25 formed with conductive traces are provided. The circuit board 25 is formed with a plurality of conductive contacts 250 on a surface thereof, and the conductive contacts 250 of the circuit board 25 correspond in position to the conductive contacts 230 of the semiconductor chip 23 embedded in the cavity 220 of the supporting plate 22.

The ACF layer 24 may firstly be applied to a side of the supporting plate 22 embedded with the semiconductor chip 23 and exposing the conductive contacts 230 (as shown in FIG. 2B), such that the supporting plate 22 can subsequently be mounted or pressed to the circuit board 25 by the ACF layer 24 disposed therebetween. Alternatively, the ACF layer 24 may firstly be attached to the circuit board 25 and then pressed to the supporting plate 22. The ACF layer 24 comprises an adhesive layer having conductive particles therein for use in subsequent carrying and electrical connection. The ACF layer 24 can fill a gap remaining in the cavity 220 of the supporting plate 22; or, the gap remaining in the cavity 220 of the supporting plate 22 may firstly be filled with an additional insulating adhesive, and then the ACF layer 24 is formed between the supporting plate 22 and the circuit board 25.

In addition, although the circuit board shown in this embodiment is a build-up four-layer circuit board, it can be any build-up or laminated and single-layer or multi-layer circuit board in practical fabrication. Since fabrication processes of the circuit board employ conventional technology, it is not to be further described herein.

Referring to FIG. 2D, the circuit board 25 formed with the plurality of conductive contacts 250 on the surface thereof is pressed to the supporting plate 22 by the ACF layer 24 disposed therebetween, such that after the ACF layer 24 is subjected to pressure, conductive particles 240 in the ACF layer 24 congregate to allow the conductive contacts 250 of the circuit board 25 to be electrically connected to the conductive contacts 230 of the chip 23 embedded in the support board 22 (as shown in FIG. 2E). Accordingly, the chip 23 is directly electrically connected to the circuit board 25 by means of the ACF layer 24 having the plurality of conductive particles 240 therein, thereby reducing the conventional steps and costs of an electrical connecting process as compared to the conventional technology.

Further referring to FIG. 2D, by the foregoing fabrication method, a circuit board structure integrated with semiconductor chip is also provided in the present invention, comprising: a supporting plate 22, which can be a general carrier board or circuit board, wherein the supporting plate 22 is formed with at least one through cavity 220; at least one semiconductor chip 23 received in the cavity 220 of the supporting plate 22 and having a plurality of conductive contacts 230, wherein the conductive contacts 230 of the semiconductor chip 23 comprise electrode pads and conductive bumps formed on the electrode pads; and at least one circuit board 25 having a plurality of conductive contacts 250 on a surface thereof, and mounted to the supporting plate 22 by means of an anisotropic conductive film (ACF) layer 24 disposed therebetween, such that the conductive contacts 250 of the circuit board 25 are electrically connected to the conductive contacts 230 of the semiconductor chip 23 via the ACF layer 24. The circuit board 25 can be a build-up or laminated and single-layer or multi-layer circuit board formed with conductive traces.

Therefore, by the circuit board structure integrated with semiconductor chip and the method of fabricating the same in the present invention, at least one semiconductor chip formed with conductive contacts on a surface thereof is provided in advance and is received in a supporting plate formed with a cavity, such that an overall thickness of a semiconductor device can be reduced to satisfy the light-weight and small-size requirements. Further, by means of an anisotropic conductive film (ACF) layer, a circuit board formed with conductive traces is pressed to the supporting plate embedded with the semiconductor chip, allowing conductive contacts of the circuit board to be electrically connected to the conductive contacts of the chip via the ACF layer so as to form the circuit board structure integrated with semiconductor chip. This can combine fabrication of a chip carrier and processes of semiconductor packaging technology to provide greater flexibility in response to clients' requirements and simplify process and interface integration for semiconductor manufacturers, as well as avoid problems associated with electrical connection and molding during conventional semiconductor packaging processes.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method of fabricating a circuit board structure integrated with semiconductor chip, comprising the steps of:
providing a supporting plate formed with at least one cavity, and receiving at least one semiconductor chip in the cavity, the semiconductor chip having a plurality of conductive contacts;
providing a circuit board formed with a plurality of conductive contacts on a surface thereof, wherein the conductive contacts of the circuit board correspond in position to the conductive contacts of the semiconductor chip; and
providing an anisotropic conductive film layer for mounting the circuit board to the supporting plate with the anisotropic conductive film layer being pressed therebetween, and for electrically connecting the conductive contacts of the circuit board to the conductive contacts of the semiconductor chip received in the cavity of the supporting plate.

2. The method of claim 1, wherein the conductive contacts of the semiconductor chip comprise electrode pads and conductive bumps formed on the electrode pads.

3. The method of claim 1, wherein the anisotropic conductive film layer is firstly disposed on a side of the supporting plate received with the semiconductor chip and exposing the conductive contacts thereof, and then is pressed to the circuit board.

4. The method of claim 1, wherein the anisotropic conductive film layer is firstly disposed on a side of the circuit board formed with the conductive contacts, and then is pressed to the supporting plate.

5. The method of claim 1, wherein the supporting plate is a metallic plate, an insulating plate, or a circuit board.

6. The method of claim 1, further comprising forming a carrier on a side of the supporting plate to seal a side of the cavity and carry the semiconductor chip.

7. The method of claim 6, wherein the carrier may be an adhesive layer.

8. The method of claim 1, wherein the cavity of the supporting plate is filled with the anisotropic conductive film layer.

9. The method of claim 1, wherein the anisotropic conductive film layer comprises conductive particles therein.

10. The method of claim 1, further comprising filling an insulating adhesive in the cavity of the supporting plate before forming the anisotropic conductive film layer on the supporting plate.

11. A circuit board structure integrated with semiconductor chip, comprising:
a supporting plate having at least one cavity;
at least one semiconductor chip having a plurality of conductive contacts and received in the cavity; and
at least one circuit board having a plurality of conductive contacts on a surface thereof, and mounted to the supporting plate by means of an anisotropic conductive film layer pressed therebetween, such that the conductive contacts of the circuit board are electrically connected to the conductive contacts of the semiconductor chip via the anisotropic conductive film layer.

12. The circuit board structure of claim 11, wherein the conductive contacts of the semiconductor chip comprise electrode pads and conductive bumps formed on the electrode pads.

13. The circuit board structure of claim 11, wherein the conductive contacts of the circuit board correspond in position to the conductive contacts of the semiconductor chip.

14. The circuit board structure of claim 11, wherein the supporting plate is a metallic plate, an insulating plate, or a circuit board.

15. The circuit board structure of claim 11, further comprising a carrier disposed on a side of the supporting plate to seal a side of the cavity and carry the semiconductor chip.

16. The circuit board structure of claim 11, wherein the conductive contacts of the semiconductor chip are covered by the anisotropic conductive film layer.

17. The circuit board structure of claim 11, wherein the anisotropic conductive film layer comprises conductive particles therein.

18. The circuit board structure of claim 11, wherein the cavity of the supporting plate is filled with the anisotropic conductive film layer.

19. The circuit board structure of claim 11, wherein the cavity of the supporting plate is filled with an insulating adhesive.
